(19) United States
(12) Patent Application Publication
(10) Pub. No.: US 2004/0092048 A1
(43) Pub. Date: May 13, 2004

(54) Angle control system including a display device configured with two imaging windows that simultaneously display the same image captured by a single camera

(76) Inventor: Chiu-Tien Hsu, Taichung City (TW)

Correspondence Address: GREENBERG TRAURIG LLP, 2450 COLORADO AVENUE, SUITE 400E, SANTA MONICA, CA, 90404, US

(21) Appl. No.: 10/294,882

(22) Filed: Nov. 13, 2002

(51) Int. Cl. H01L 21/66; H01L 21/46; H01L 21/78

(52) U.S. Cl. 438/17; 438/462

(57) ABSTRACT

An angle control system includes a platform for holding a patterned work piece, a drive unit for driving rotary movement of the platform, a camera unit for generating an electrical output corresponding to an image of the patterned work piece, a signal converter for converting the electrical output of the camera unit into digital image data, a processing apparatus for receiving the digital image data from the signal converter, a display device configured with left and right imaging windows for displaying the same image corresponding to the digital image data simultaneously thereon, and a movement control device for controlling the drive unit to rotate the platform. The work piece is positioned at a required position when identical sections of the images of the patterned work piece shown simultaneously on the left and right imaging windows are aligned with each other.

### BACKGROUND OF THE INVENTION

1. Field of the Invention

The invention relates to an angle control system for positioning a patterned semiconductor wafer during a wafer cutting operation, more particularly to an angle control system including a display device configured with two imaging windows that simultaneously display the same image captured by a single camera.

2. Description of the Related Art

In order to increase competitiveness, there is always a need to shorten the amount of time required to deliver products to customers.

Referring to FIG. 1, a conventional wafer cutting apparatus 100 is shown to include a platform 1 adapted for holding a patterned semiconductor wafer 101, a wafer cutting unit 2, a camera unit 3 including a camera lens 301, an analog-to-digital (A/D) converter 401 coupled electrically to the camera unit 3, an image frame memory 402 coupled electrically to the A/D converter 401, a central processing unit (CPU) 4 coupled electrically to the image frame memory 402, a display device 5 coupled electrically to the CPU 4, a movement control device 6 coupled electrically to the CPU 4, and a drive unit 7 coupled electrically to the movement control device 6. The drive unit 7 includes an X-direction driver 701 and a θ-direction driver 702 coupled to and driving movement of the platform 1 in the X-direction and the θ-direction, respectively. The drive unit 7 further includes a Y-direction driver 703 coupled to and driving movement of the wafer cutting unit 2 and the camera unit 3 in the Y-direction, and a Z-direction driver 704 coupled to and driving movement of the wafer cutting unit 2 in the Z-direction. Each of the drivers 701-704 includes a stepper motor. The movement control device 6 is manually operable to control the driver 701 to move the platform 1 in the X-direction, to control the driver 702 to rotate the platform 1 in the θ-direction, to control the driver 703 to move the wafer cutting unit 2 and the camera unit 3 in the Y-direction, and to control the driver 704 to move the wafer cutting unit 2 in the Z-direction.

During a wafer cutting operation, the semiconductor wafer 101 is placed on the platform 1, and the camera unit 3 will generate an electrical output corresponding to at least a part of an image of the patterned surface of the semiconductor wafer 101 on the platform 1. The A/D converter 401 converts the electrical output of the camera unit 3 into digital image data that is stored in the image frame memory 402. The CPU 4 retrieves the digital image data from the image frame memory 402, and controls the display device 5 to display an image corresponding to the digital image data thereon.

The semiconductor wafer 101 is formed with an array of polygonal circuit areas, adjacent ones of the polygonal circuit areas being spaced apart by cutting streets. Simultaneous with the display of the image corresponding to the digital image data, the display device 5 is configured to further display reference marks thereon. Therefore, to position the semiconductor wafer 101 at a required position for cutting, the operator of the wafer cutting apparatus 100 operates the movement control device 6 to align boundaries of the polygonal circuit areas shown on the display device 5 with the reference marks. Adjustment of the position of the semiconductor wafer 101 in the conventional wafer cutting apparatus 100 involves initial rough adjustment of the platform 1 in the θ-direction, initial adjustment of the camera unit 3 in the Y-direction, tuning adjustment of the platform 1 in the θ-direction, adjustment of the platform 1 in the X-direction, another tuning adjustment of the platform 1 in the θ-direction, tuning adjustment of the camera unit 3 in the Y-direction, etc.

Because the semiconductor wafer 101 cannot be adjusted to the correct position in the θ-direction in a single manual adjustment operation by merely referring to the reference marks shown on the display device 5, repeated tuning adjustment is required in the conventional wafer cutting apparatus 100. Therefore, positioning of the semiconductor wafer 101 at a required position in the conventional wafer cutting apparatus 100 is both inconvenient and time-consuming.

### SUMMARY OF THE INVENTION

Therefore, the main object of the present invention is to provide an angle control system to be incorporated in a wafer cutting apparatus so as to overcome the aforesaid drawbacks associated with the prior art.

More specifically, the object of the present invention is to provide an angle control system including a display device configured with two imaging windows that simultaneously display the same image captured by a single camera to facilitate accurate positioning of a semiconductor wafer at a required angular position.

Accordingly, the angle control system of the present invention is used to position a work piece having a patterned surface at a required position, and comprises:

a platform adapted for holding the work piece;

a drive unit coupled to and operable so as to drive rotary movement of the platform;

a camera unit disposed above the platform and operable so as to generate an electrical output corresponding to at least a part of an image of the patterned surface of the work piece;

a signal converter coupled electrically to the camera unit and operable so as to convert the electrical output of the camera unit into digital image data;

a processing apparatus coupled electrically to the signal converter so as to receive the digital image data therefrom;

a display device coupled electrically to the processing apparatus and configured with left and right imaging windows, the left and right imaging windows displaying the same image corresponding to the digital image data simultaneously thereon; and

a movement control device coupled electrically to the drive unit and operable so as to generate control signals for controlling the drive unit to rotate the platform, whereby the work piece is positioned at the required position when identical sections of the images of the patterned surface of the work piece shown simultaneously on the left and right imaging windows are aligned with each other.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic block diagram of a conventional wafer cutting apparatus;

FIG. 2 is a perspective view of a wafer cutting apparatus that incorporates the preferred embodiment of an angle control system according to the present invention;

FIG. 3 is a perspective view illustrating the wafer cutting apparatus of FIG. 2 with a housing removed therefrom;

FIG. 4 is a schematic block diagram of the wafer cutting apparatus of FIG. 2;

FIG. 5 is a top view showing a semiconductor wafer on a platform of the angle control system;

FIG. 6 illustrates images displayed by a display device of the angle control system prior to adjustment;

FIG. 7 illustrates images displayed by the display device of the angle control system during adjustment;

FIG. 8 is a top view showing the semiconductor wafer at a position corresponding to FIG. 7;

FIG. 9 illustrates images displayed by the display device of the angle control system after adjustment;

FIG. 10 is a top view showing the semiconductor wafer at a required adjusted position corresponding to FIG. 9;

FIG. 11 illustrates images of a semiconductor wafer having hexagonal circuit areas displayed by the display device of the angle control system prior to adjustment; and

FIG. 12 illustrates images of the semiconductor wafer having hexagonal circuit areas displayed by the display device of the angle control system after adjustment.

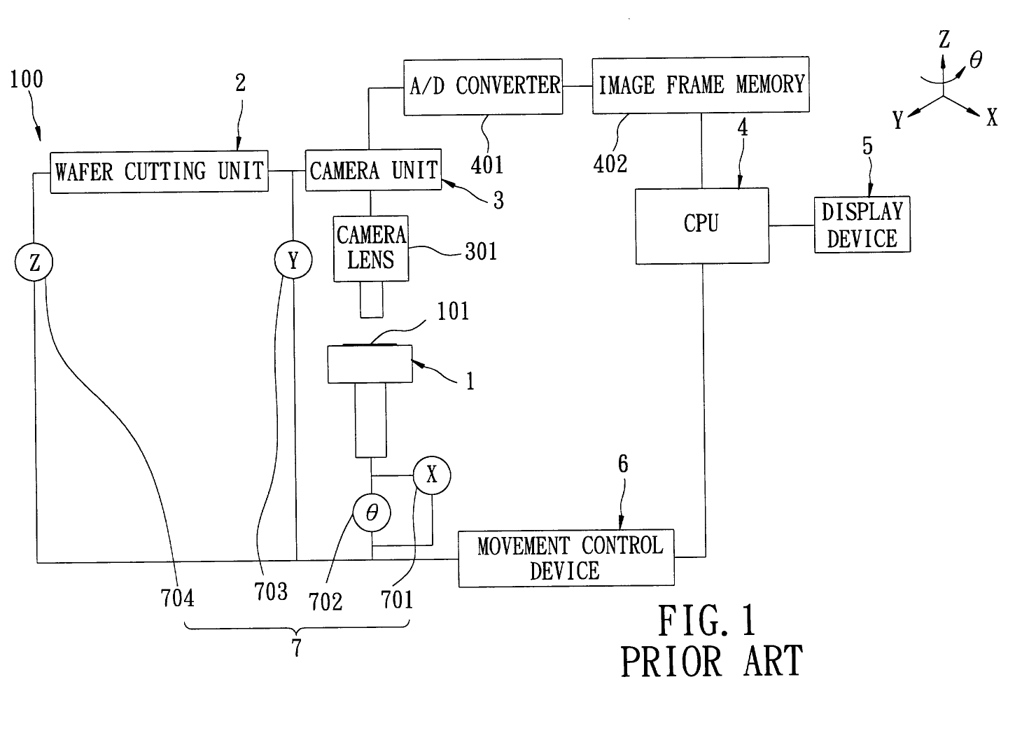

### DETAILED DESCRIPTION OF THE PREFERRED EMBODIMENT

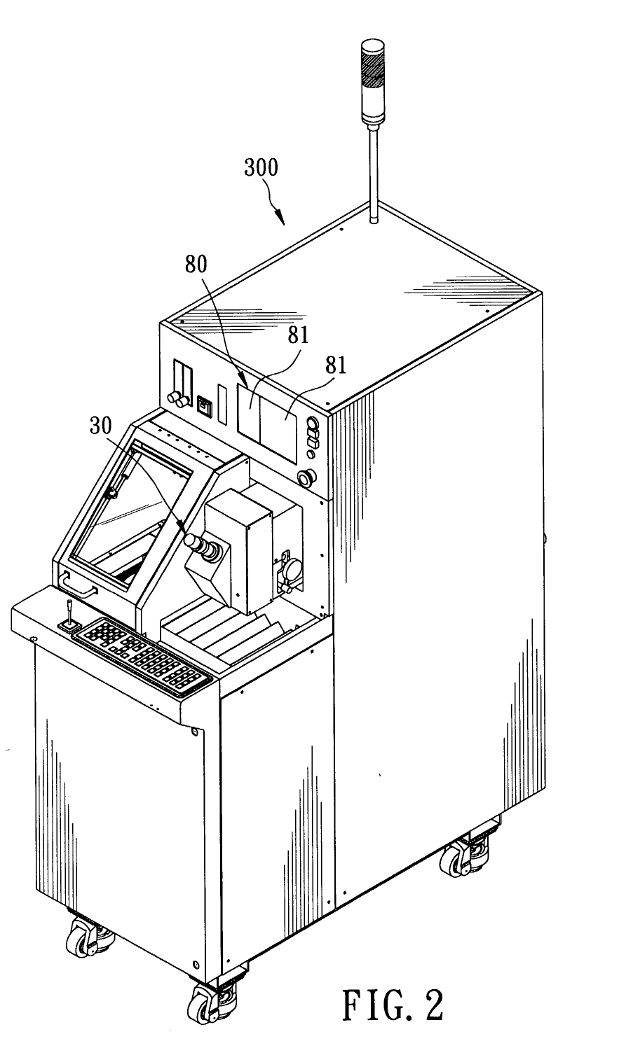

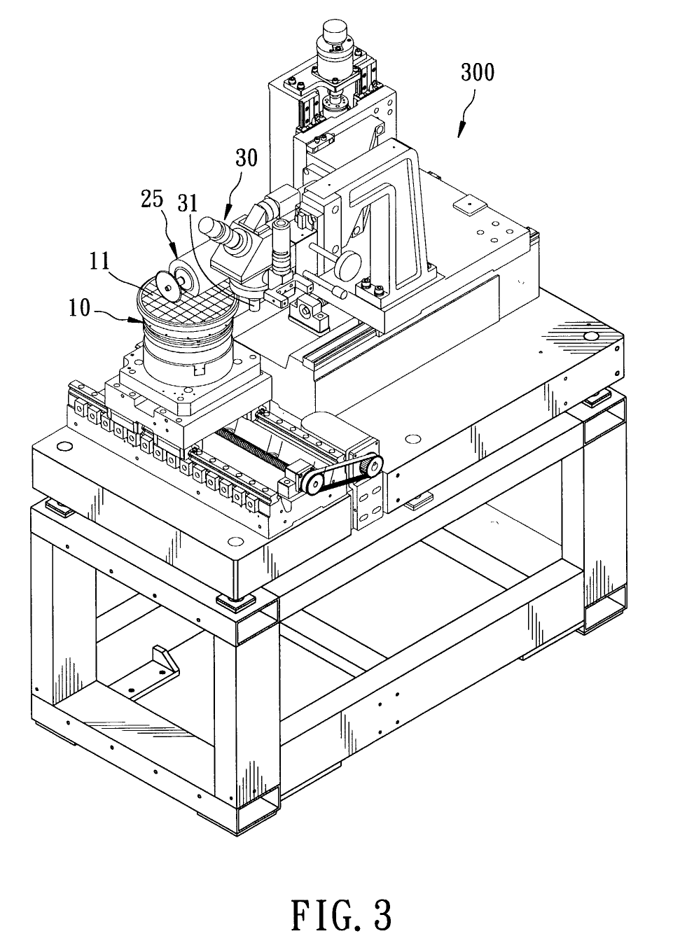

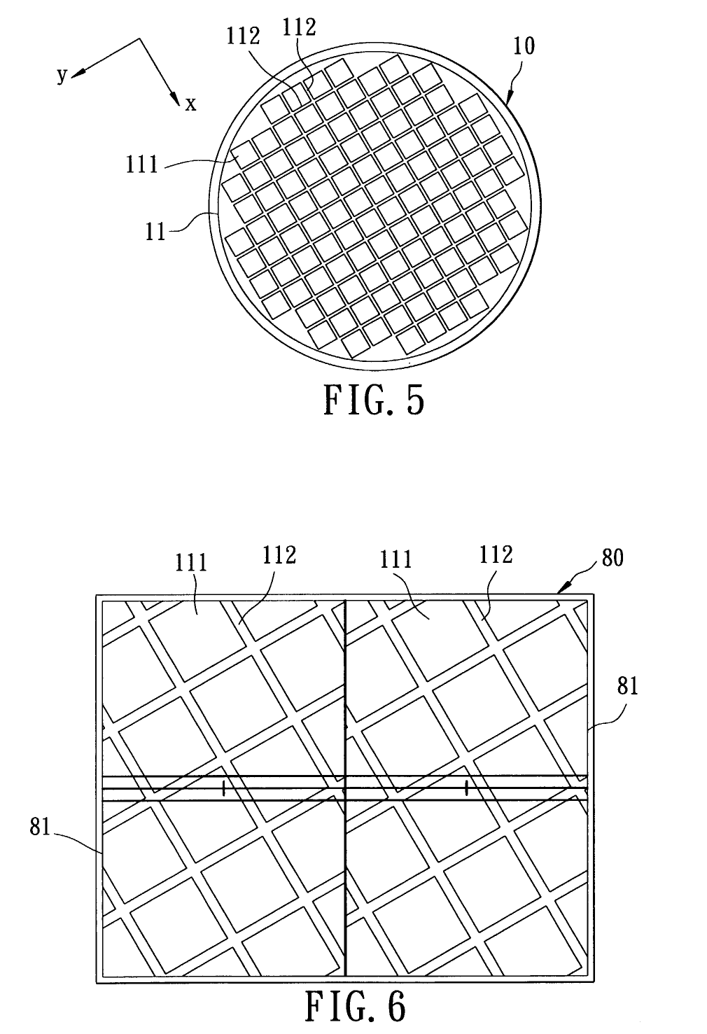

Referring to FIGS. 2, 3 and 4, the preferred embodiment of an angle control system 200 according to the present invention is shown to be incorporated in a known wafer cutting apparatus 300 for positioning a semiconductor wafer 11 having a patterned top surface (see FIG. 5) at a required position during a wafer cutting operation. The angle control system 200 includes a platform 10 adapted for holding the semiconductor wafer 11, a drive unit 20, a camera unit 30 including a camera lens 31, an analog-to-digital (A/D) signal converter 40 coupled electrically to the camera unit 30, a processing apparatus 400 coupled electrically to the signal converter 40, a display device 80 coupled electrically to the processing apparatus 400, and a movement control device 90 coupled electrically to the drive unit 20.

As shown in FIG. 5, the semiconductor wafer 11 is formed with an array of rectangular circuit areas 111. Adjacent ones of the circuit areas 111 are spaced apart by linear cutting streets 112.

The drive unit 20 includes an X-direction driver 22 and a θ-direction driver 21 coupled to and driving movement of the platform 10 in the X-direction and the θ-direction, respectively. The drive unit 20 further includes a Y-direction driver 23 coupled to and driving movement of a wafer cutting unit 25 and the camera unit 30 in the Y-direction, and a Z-direction driver 24 coupled to and driving movement of the wafer cutting unit 25 in the Z-direction. Each of the drivers 21-24 includes a stepper motor.

The camera unit 30 is disposed above the platform 10 and is operable in a conventional manner so as to generate an analog electrical output corresponding to at least a part of an image of the patterned top surface of the semiconductor wafer 11.

The A/D signal converter 40 is operable in a conventional manner so as to convert the analog electrical output of the camera unit 30 into digital image data.

The processing apparatus 400 includes an image frame memory 50, a processor 60, and a display memory 70. The image frame memory 50 is coupled electrically to the A/D signal converter 40 for storing the digital image data therein. The processor 60, such as a CPU, is coupled electrically to the image frame memory 50, and is capable of receiving and processing the digital image data stored in the image frame memory 50. The display memory 70 is coupled electrically to the processor 60, has first and second memory portions 71, and is controlled by the processor 60 to store processed image data corresponding to that stored in the image frame memory 50 in each of the first and second memory portions 71.

When the angle control system 200 executes a proprietary computer program product according to this invention, the display device 80 will be configured with left and right imaging windows 81 that are rectangular in shape and that have the same size. The left and right imaging windows 81 display the same image corresponding to the processed image data stored in the first and second memory portions 71 simultaneously thereon.

Moreover, due to the proprietary computer program product, the movement control device 90, which includes known user input devices, such as a keyboard and a joystick (see FIG. 2), and which is further coupled electrically to the processor 60, will be configured to permit manual operation thereof so as to generate control signals for controlling the drive unit 20.

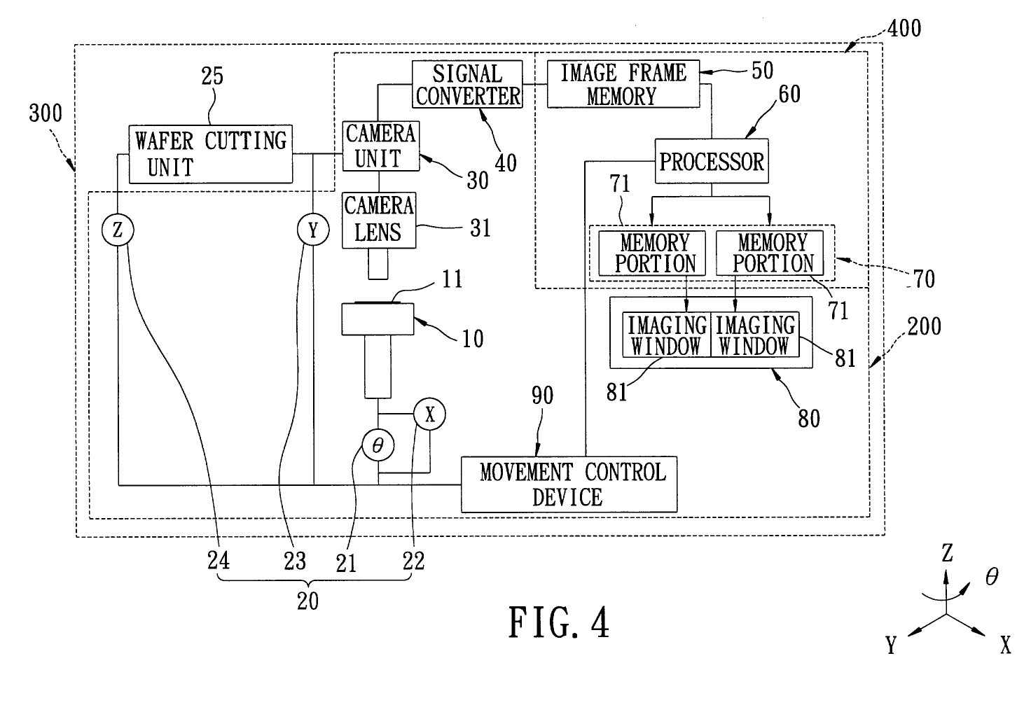

Referring again to FIGS. 4 and 5, in use, the semiconductor wafer 11 is placed on the platform 10, and the camera unit 30 generates an electrical output corresponding to at least a part of an image of the patterned surface of the semiconductor wafer 11 on the platform 10. The electrical output is converted into digital image data by the A/D signal converter 40. The digital image data is stored in the image frame memory 50 and is processed by the processor 60, and processed image data corresponding to the data in the image frame memory 50 are stored in each of the first and second memory portions 71 of the display memory 70. Thereafter, the display device 80 simultaneously displays the same image on the left and right imaging windows 81 according to the processed image data stored in the first and second memory portions 71, as best shown in FIG. 6.

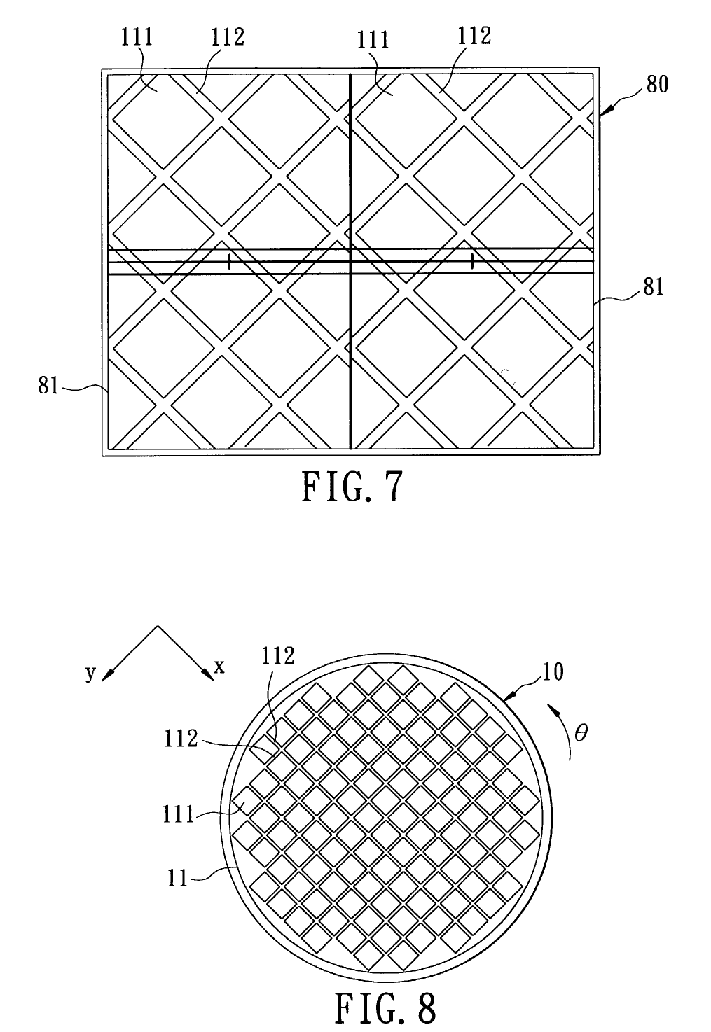

Subsequently, as shown in FIGS. 7 and 8, the operator of the wafer cutting apparatus 300 can manipulate the movement control device 90 with reference to the images shown on the left and right imaging windows 81 of the display device 80 so as to generate control signals for controlling the θ-direction driver 21 to rotate the platform 10 in the θ-direction. The images shown on the left and right imaging windows 81 are correspondingly rotated as a result.

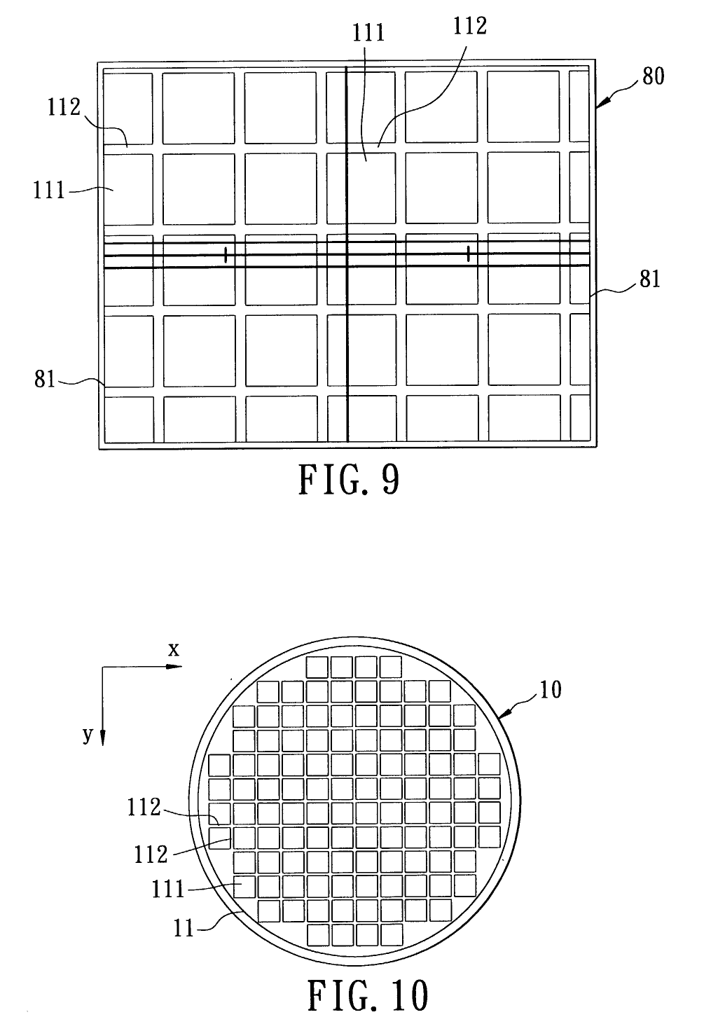

Referring to FIG. 9, the operator continues to manipulate the movement control device 90 until identical boundaries of the rectangular circuit areas 111 of the patterned surface of the semiconductor wafer 11 shown simultaneously on the left and right imaging windows 81 of the display device 80 are in horizontal alignment with each other. The semiconductor wafer 11 is positioned at the correct angular position for wafer cutting at this time, as best shown in FIG. 10.

After adjustment in the θ-direction, Y-direction and X-direction adjustment can be conducted in a conventional manner before proceeding further with the wafer cutting operation.

Since positioning of the semiconductor wafer 11 at the correct angular position only requires adjustment until identical boundaries of the rectangular circuit areas 111 of the patterned surface of the semiconductor wafer 11 shown simultaneously on the left and right imaging windows 81 of the display device 80 are in horizontal alignment with each other, the angle control system 200 of the present invention is less complicated and less time-consuming as compared to the prior art described hereinabove. It is therefore evident that the angle control system 200 of this invention can shorten the time required for wafer cutting to increase the production rate.

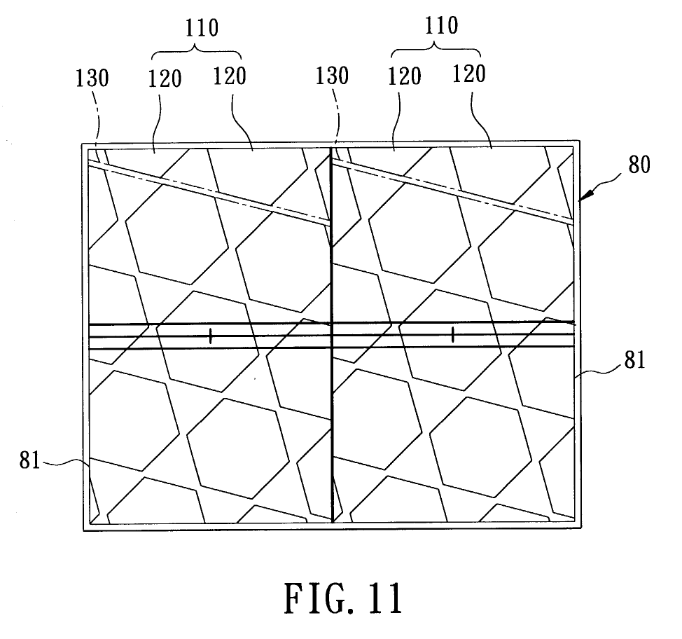

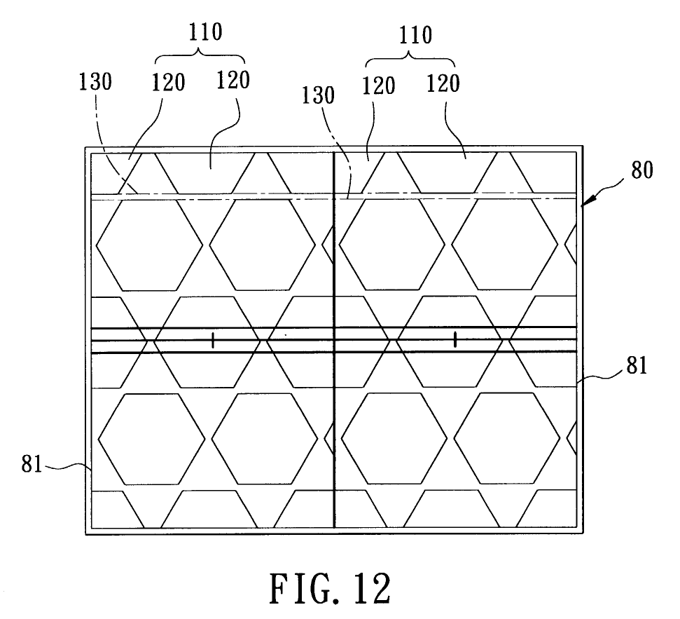

Furthermore, it should be noted that the angle control system 200 of this invention is also suitable for positioning a semiconductor wafer having hexagonal circuit areas during a wafer cutting operation. FIG. 11 illustrates images of a semiconductor wafer 110 having hexagonal circuit areas 120 displayed by left and right imaging windows 81 of the display device 80 of the angle control system of this invention prior to adjustment. Adjacent ones of the circuit areas 120 are spaced apart by cutting streets 130. FIG. 12 illustrates images of the semiconductor wafer 110 displayed by the left and right imaging windows 81 of the display device 80 of the angle control system of this invention after adjustment. The semiconductor wafer 110 is at the required angular position when identical boundaries of the circuit areas 120 shown simultaneously on the left and right imaging windows 81 are in horizontal alignment with each other.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. An angle control system for positioning a work piece having a patterned surface at a required position, said angle control system comprising:
a platform adapted for holding the work piece;
a drive unit coupled to and operable so as to drive rotary movement of said platform;
a camera unit disposed above said platform and operable so as to generate an electrical output corresponding to at least a part of an image of the patterned surface of the work piece;
a signal converter coupled electrically to said camera unit and operable so as to convert the electrical output of said camera unit into digital image data;
a processing apparatus coupled electrically to said signal converter so as to receive the digital image data therefrom;
a display device coupled electrically to said processing apparatus and configured with left and right imaging windows, said left and right imaging windows displaying the same image corresponding to the digital image data simultaneously thereon; and
a movement control device coupled electrically to said drive unit and operable so as to generate control signals for controlling said drive unit to rotate said platform, whereby the work piece is positioned at the required position when identical sections of the images of the patterned surface of the work piece shown simultaneously on said left and right imaging windows are aligned with each other.

2. The angle control system as claimed in claim 1, wherein said processing apparatus includes:
an image frame memory coupled electrically to said signal converter for storing the digital image data therein;
a processor coupled electrically to said image frame memory; and
a display memory coupled electrically to said processor and said display device, said display memory having first and second memory portions and being controlled by said processor to store processed image data corresponding to that stored in said image frame memory in each of said first and second memory portions;
the images shown by said display device on said left and right imaging windows corresponding to the processed image data stored in said first and second memory portions, respectively.

3. The angle control system as claimed in claim 1, wherein said drive unit includes a stepper motor.

4. The angle control system as claimed in claim 1, wherein the work piece is a semiconductor wafer formed with an array of polygonal circuit areas, adjacent ones of the polygonal circuit areas being spaced apart by cutting streets, whereby the work piece is positioned at the required position when identical boundaries of the polygonal circuit areas of the patterned surface of the work piece shown simultaneously on said left and right imaging windows are in horizontal alignment with each other.

5. A method for positioning a work piece having a patterned surface at a required position, comprising the steps of:
placing the work piece on a platform;
generating an electrical output corresponding to at least a part of an image of the patterned surface of the work piece on the platform;
converting the electrical output into digital image data;
configuring a display device with left and right imaging windows for displaying the same image corresponding to the digital image data simultaneously thereon; and
rotating the platform so that the work piece is positioned at the required position when identical sections of the images of the patterned surface of the work piece shown simultaneously on the left and right imaging windows are aligned with each other.

6. The method as claimed in claim 5, wherein the work piece is a semiconductor wafer formed with an array of polygonal circuit areas, adjacent ones of the polygonal circuit areas being spaced apart by cutting streets, whereby the work piece is positioned at the required position when identical boundaries of the polygonal circuit areas of the patterned surface of the work piece shown simultaneously on the left and right imaging windows are in horizontal alignment with each other.

7. A computer program product for a system that includes
a platform adapted for holding a work piece having a patterned surface,
a drive unit coupled to and operable so as to drive rotary movement of the platform,
a camera unit disposed above the platform and operable so as to generate an electrical output corresponding to at least a part of an image of the patterned surface of the work piece,
a signal converter coupled electrically to the camera unit and operable so as to convert the electrical output of the camera unit into digital image data,
a processing apparatus coupled electrically to the signal converter so as to receive the digital image data therefrom,
a display device coupled electrically to the processing apparatus, and
a movement control device coupled electrically to the drive unit,
said computer program product enabling said system to perform steps for positioning the work piece at a required position, the steps for positioning comprising:
configuring the display device with left and right imaging windows for displaying the same image corresponding to the digital image data simultaneously thereon; and
configuring the movement control device to permit manual operation thereof so as to generate control signals for controlling the drive unit to rotate the platform, whereby the work piece is positioned at the required position when identical sections of the images of the patterned surface of the work piece shown simultaneously on the left and right imaging windows are aligned with each other.

8. The computer program product as claimed in claim 7, wherein the work piece is a semiconductor wafer formed with an array of polygonal circuit areas, adjacent ones of the polygonal circuit areas being spaced apart by cutting streets, whereby the work piece is positioned at the required position when identical boundaries of the polygonal circuit areas of the patterned surface of the work piece shown simultaneously on the left and right imaging windows are in horizontal alignment with each other.
